(19) United States
(12) Patent Application Publication
(10) Pub. No.: US 2025/0089403 A1
(43) Pub. Date: Mar. 13, 2025

(54) TRANSPARENT DISPLAY DEVICE

(71) Applicant: AUO Corporation, Hsinchu (TW)

(72) Inventors: YuTang Tsai, Hsinchu (TW); Wang-Shuo Kao, Hsinchu (TW); Jia Hao Hsu, Hsinchu (TW); Kun-Cheng Tien, Hsinchu (TW); Jia-Long Wu, Hsinchu (TW)

(73) Assignee: AUO Corporation, Hsinchu (TW)

(21) Appl. No.: 18/523,903

(22) Filed: Nov. 30, 2023

(30) Foreign Application Priority Data
Sep. 13, 2023 (TW) 112134813

(51) Int. Cl. H01L 33/20; H01L 25/075; H01L 27/15

(52) U.S. Cl. CPC H10H 20/819; H01L 25/0753; H10H 29/142

(57) ABSTRACT

A transparent display device includes a transparent display panel and a functional film. The transparent display panel includes a transparent substrate and a pixel array. The functional film is disposed on the transparent display panel. The pixel array is located between the functional film and the transparent substrate. A surface of the functional film facing away from the transparent substrate has raised microstructures. At least a portion of each of the raised microstructures extends in a first oblique direction. A size of the least a portion of each of the raised microstructures is gradually decreased along the first oblique direction. The first oblique direction forms an acute angle α with a normal direction of the transparent substrate.

### CROSS-REFERENCE TO RELATED APPLICATION

This application claims the priority benefit of Taiwan application serial no. 112134813, filed on Sep. 13, 2023. The entirety of the above-mentioned patent application is hereby incorporated by reference herein and made a part of this specification.

### BACKGROUND

### Technical Field

The present disclosure relates to a display device, and in particular to a transparent display device.

### Description of Related Art

A transparent display device refers to a display device that allows the user to see the scene behind the user through a transparent display state, and such transparent display device is normally seen in showcases, vending machines, etc. The transparent display device has a display region and a transparent region. The display region may provide a display screen for the user to see, and the transparent region is transparent so that the user is able to see the scene behind the user. Pixels are provided in the display region to emit image beams toward the display surface of the transparent display device to provide the screen. However, part of the image beam will be reflected back into the interior of the transparent display device at the interface between the display surface and the outer environment, and then pass through the back surface of the transparent display device, which cases a backside light leakage problem.

### SUMMARY

The present disclosure provides a transparent display device that may improve the backside light leakage problem.

The transparent display device of the present disclosure includes a transparent display panel and a functional film. The transparent display panel includes a transparent substrate and a pixel array. The transparent substrate has multiple display regions and multiple transparent regions. The pixel array is disposed on the transparent substrate. The pixel array includes multiple pixels and multiple openings. A plurality of pixels are disposed in an array along the first direction and the second direction, wherein the first direction and the second direction are interleaved, and each pixel overlaps with a corresponding display region. Each opening is surrounded by a portion of multiple pixels, and each opening overlaps with a corresponding transparent region. The functional film is disposed on the transparent display panel. The pixel array is located between the functional film and the transparent substrate. There are a plurality of raised microstructures on the surface of the functional film facing away from the transparent substrate. At least a portion of each raised microstructure extends in a first oblique direction. The size of at least a portion of each raised microstructure is gradually decreased along the first oblique direction. The first oblique direction forms an acute angle α with a normal direction of the transparent substrate.

### BRIEF DESCRIPTION OF THE DRAWINGS

FIG. 1 is a schematic side view of a transparent display device according to an embodiment of the present disclosure.

FIG. 2 is a schematic top view of a transparent display device according to an embodiment of the present disclosure.

FIG. 3 is a schematic cross-sectional view of a functional film according to an embodiment of the present disclosure.

FIG. 4A shows a cross-section of FIG. 3 and a cross-section of the raised microstructure segmented by the cross-section.

FIG. 4B shows another cross-section of FIG. 3 and a cross-section of the raised microstructure segmented by the other cross-section.

FIG. 4C shows yet another cross-section of FIG. 3 and a cross-section of the raised microstructure segmented by yet another cross-section.

FIG. 4D shows still another cross-section of FIG. 3 and a cross-section of the raised microstructure segmented by still another cross-section.

FIG. 5 is a schematic side view of a transparent display device according to a comparative example of the present disclosure.

FIG. 6 is a schematic cross-sectional view of a transparent display device according to another embodiment of the present disclosure.

FIG. 7 is a schematic cross-sectional view of a transparent display device according to yet another embodiment of the present disclosure.

FIG. 8 is a schematic cross-sectional view of a transparent display device according to still another embodiment of the present disclosure.

FIG. 9 is a schematic cross-sectional view of a transparent display device according to an embodiment of the present disclosure.

### DESCRIPTION OF THE EMBODIMENTS

Reference will now be made in detail to the exemplary embodiments of the present disclosure, examples of which are illustrated in the accompanying drawings. Whenever possible, the same reference numbers are used in the drawings and descriptions to refer to the same or similar parts.

It should be understood that when an element such as a layer, film, region or substrate is referred to as being “on another element,” “connected to another element,” it can be directly on or connected to the other element, or intervening elements may also be present. In contrast, when an element is referred to as being “directly on” or “directly connected to” another element, there are no intervening elements present. As used herein, the term “connected” may refer to physically connected and/or electrically connected. Furthermore, “electrical connection” or “coupling” may mean the presence of other elements between two elements.

The term “about,” “approximately,” “similar,” or “substantially” as used herein is inclusive of the stated value and means within an acceptable range of deviation for the particular value as determined by people having ordinary skill in the art, considering the measurement in question and the error associated with measurement of the particular quantity (i.e., the limitations of the measurement system) or the limitations of the manufacturing system. For instance, “about” may mean within one or more standard deviations, or within, for example, ±30%, ±20%, ±10%, or ±5% of the stated value. Furthermore, the terms “about”, “approximately” or “substantially” used herein may be used to select a more acceptable deviation range or standard deviation based on optical properties, etching properties or other properties, and one standard deviation may not apply to all properties.

Unless otherwise defined, all terms (including technical and scientific terms) used herein have the same meaning as commonly understood by persons of ordinary skill in the art. It will be further understood that terms, such as those defined in commonly used dictionaries, should be interpreted as having a meaning that is consistent with their meaning in the context of the relevant art and the disclosure and will not be interpreted in an idealized or overly formal sense unless expressly so defined herein.

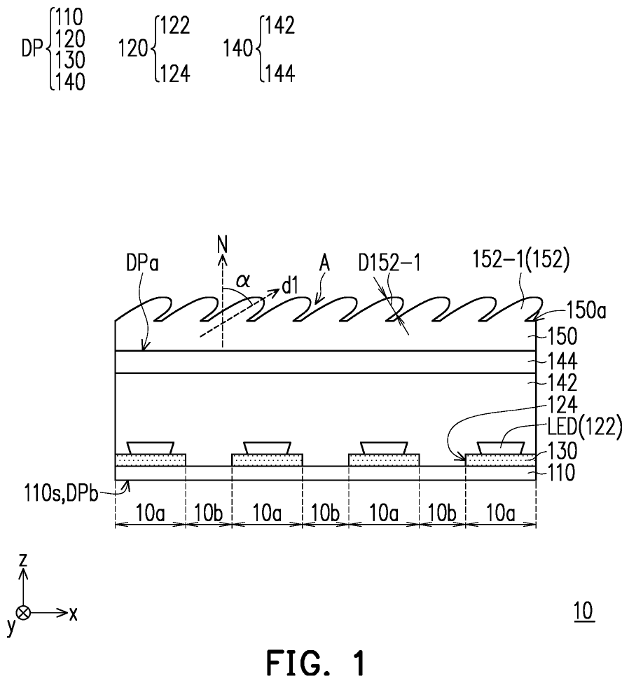

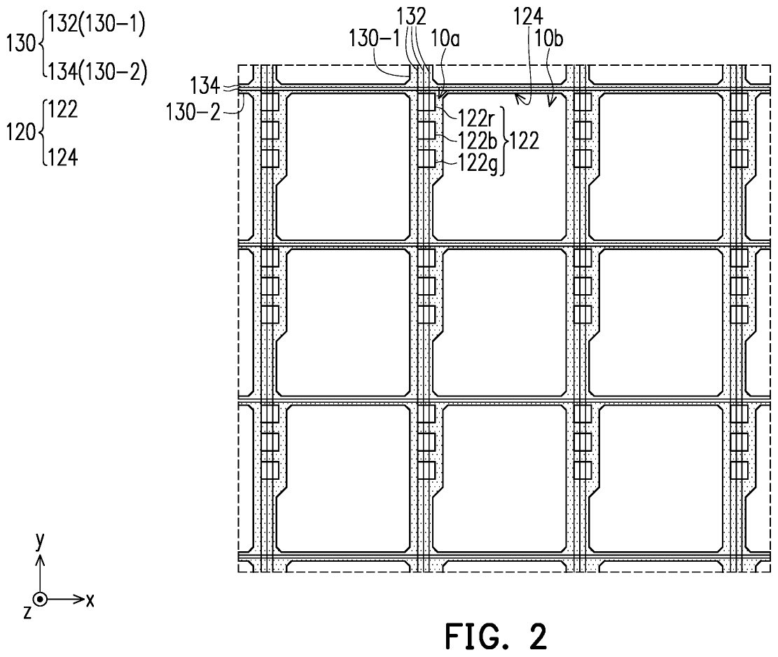

FIG. 1 is a schematic side view of a transparent display device according to an embodiment of the present disclosure. FIG. 2 is a schematic top view of a transparent display device according to an embodiment of the present disclosure. FIG. 2 omits the transparent packaging component 140 and a functional film 150 of FIG. 1.

Referring to FIG. 1 and FIG. 2, the transparent display device 10 includes a transparent display panel DP. The transparent display panel DP includes a transparent substrate 110, a pixel array 120 and a circuit structure 130. The circuit structure 130 includes a plurality of signal lines 132 and 134 and is substantially opaque. The transparent substrate 110 has a plurality of display regions 10a and a plurality of transparent regions 10b. In an embodiment, the plurality of transparent regions 10b may include multiple regions of the transparent substrate 110 that are not occupied by the circuit structure 130, and the multiple display regions 10a may be multiple regions of the transparent substrate 110 that are occupied by the circuit structure 130. For example, in an embodiment, in a top view of the transparent display device 10, the circuit structure 130 is generally a mesh structure, and the mesh structure includes a plurality of longitudinal portions 130-1 and a plurality of transverse portions 130-2 that intersect with each other. The plurality of display regions 10a may respectively correspond to a plurality of intersections of the plurality of longitudinal portions 130-1 and the plurality of transverse portions 130-2, and the plurality of transparent regions 10b may respectively correspond to a plurality of meshes of the mesh structure. However, the present disclosure is not limited thereto. In an embodiment, the transparent substrate 110 may be made of glass. However, the present disclosure is not limited thereto. In other embodiments, the material of the transparent substrate 110 may also be quartz, organic polymer, or other applicable materials.

The pixel array 120 is disposed on the transparent substrate 110. The pixel array 120 includes a plurality of pixels 122 and a plurality of openings 124. The plurality of pixels 122 are disposed in an array along the first direction y and the second direction x, wherein the first direction y and the second direction x are intersected. For example, in an embodiment, the first direction y and the second direction x may be perpendicular to each other, but the disclosure is not limited thereto. Each pixel 122 overlaps with a corresponding display region 10a in a third direction z, wherein the third direction z is perpendicular to the first direction y and the second direction x. Each opening 124 is surrounded by a portion of the plurality of pixels 122, and each opening 124 overlaps with a corresponding transparent region 10b in the third direction z. For example, in an embodiment, each opening 124 may be a closed opening, but the disclosure is not limited thereto.

In an embodiment, each pixel 122 may include a plurality of sub-pixels 122r, 122g, and 122b respectively used to emit first color light, second color light, and third color light. For example, in an embodiment, the first color light, the second color light and the third color light may be red light, green light and blue light respectively, but the disclosure is not limited thereto.

The plurality of signal lines 132 and 134 of the circuit structure 130 are disposed on the transparent substrate 110 and are electrically connected to the plurality of pixels 122. The signal lines 132 and 134 may be any wires used to drive the pixels 122. For example, in an embodiment, the circuit structure 130 further includes a plurality of pixel driving circuits (not shown). Each pixel 122 includes a light-emitting element LED, and the light-emitting element LED of each pixel 122 is electrically connected to the corresponding pixel driving circuit. The pixel driving circuit may include a first transistor (not shown), a second transistor (not shown) and a capacitor (not shown). The second terminal of the first transistor is electrically connected to the control terminal of the second transistor. The capacitor is electrically connected to the second terminal of the first transistor and the first terminal of the second transistor, and the first electrode (not shown) of the light-emitting element LED is electrically connected to the second terminal of the second transistor. The plurality of signal lines 132 and 134 may include a data line electrically connected to the first terminal of the first transistor, a scan line electrically connected to the control terminal of the first transistor and a power line electrically connected to the first terminal of the second transistor. In an embodiment, the light-emitting element LED is, for example, a light-emitting diode element, but the disclosure is not limited thereto.

In an embodiment, the signal lines 132 and 134 may include a plurality of first signal lines 132 and a plurality of second signal lines 134. The plurality of first signal lines 132 substantially extend along the first direction y, and the plurality of second signal lines 134 substantially extend along the second direction x. The longitudinal portion 130-1 and the transverse portion 130-2 of the circuit structure 130 may include a first signal line 132 and a second signal line 134 respectively. The first signal line 132 and the second signal line 134 may be straight wires or curved wires. The first signal line 132 and the second signal line 134 may be composed of the same or different patterned conductive layers. The first signal line 132 and the second signal line 134 may be a signal line of a single-layer structure or a signal line of a multi-layer stacked structure. The material of the first signal line 132 and the second signal line 134 is preferably an opaque conductive material (such as metal), but the present disclosure is not limited thereto. For example, in an embodiment, one of the first signal line 132 and the second signal line 134 is a data line, and the other of the first signal line 132 and the second signal line 134 is, for example, a scan line and/or or power line, but the present disclosure is not limited thereto.

Please refer to FIG. 1. In an embodiment, the transparent display panel DP further includes a transparent packaging component 140 disposed on the transparent substrate 110 and covering a plurality of pixels 122. The transparent packaging component 140 has a light exit surface DPa of the transparent display panel DP. Most of the light beams (not shown) emitted by the light-emitting element LED exits the transparent display panel DP from the light exit surface DPa, thereby providing the user with a display screen. The light exit surface DPa is the front surface of the transparent display panel DP. The transparent substrate 110 has a surface 110s facing away from the pixels 122, and the surface 110s is the back surface DPb of the transparent display panel DP. For example, in an embodiment, the transparent packaging component 140 may include a transparent packaging adhesive 142 covering a plurality of pixels 122 and a transparent protective cover 144 disposed on the transparent packaging adhesive 142, but the disclosure is not limited thereto. In an embodiment, the material of the transparent protective cover 144 is, for example, glass, but the disclosure is not limited thereto.

It is worth noting that the transparent display device 10 further includes a functional film 150, which is disposed on the light exit surface DPa of the transparent display panel DP. The pixel array 120 is located between the functional film 150 and the transparent substrate 110. There are a plurality of raised microstructures 152 on the surface 150a of the functional film 150 facing away from the transparent substrate 110. At least a portion of each raised microstructure 152 (for example, the first portion 152-1) extends in the first oblique direction d1. The size D152-1 of at least a portion of each raised microstructure 152 (for example, the first portion 152-1) is gradually decreased along the first oblique direction d1, and the first oblique direction d1 forms an acute angle α with a normal direction N of the transparent substrate 110.

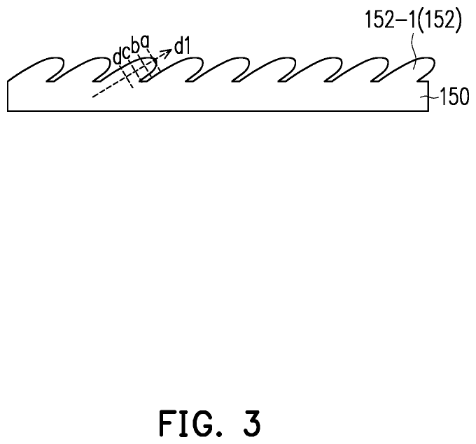

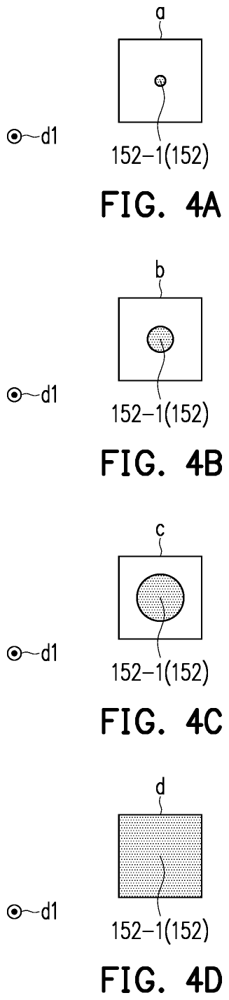

FIG. 3 is a schematic cross-sectional view of a functional film according to an embodiment of the present disclosure. FIG. 3 shows a plurality of cross-sections d, c, b, and a on a raised microstructure 152 of the functional film 150, wherein the plurality of cross-sections d, c, b, and a are perpendicular to the first oblique direction d1 and arranged in order along the first oblique direction d1. FIG. 4A shows a cross-section a of FIG. 3 and a cross-section of the raised microstructure 152 segmented by the cross-section a. FIG. 4B shows another cross-section b of FIG. 3 and a cross-section of the raised microstructure 152 segmented by the other cross-section b. FIG. 4C shows yet another cross-section c of FIG. 3 and a cross-section of the raised microstructure 152 segmented by the yet another cross-section c. FIG. 4D shows still another cross-section d of FIG. 3 and a cross-section of the raised microstructure 152 segmented by the still another cross-section d.

Please refer to FIG. 1, FIG. 3, FIG. 4A, FIG. 4B, FIG. 4C and FIG. 4D. The size D152-1 of at least a portion of each raised microstructure 152 is gradually decreased along the first oblique direction, which may mean that: the cross-sectional area of the raised microstructure 152 segmented by the plurality of cross-sections d, c, b, and a sequentially arranged along the first oblique direction d1 gradually becomes smaller.

The equivalent refractive index of the plurality of raised microstructures 152 and a portion of the external environment medium A located between the plurality of raised microstructures 152 will change smoothly with the light exit surface DPa that is away from the transparent display device 10. The functional film 150 may suppress the reflection of light beams (not shown) that are obliquely incident on the light exit surface DPa from the interior of the transparent display panel DP, thereby reducing the amount of light beams leaking from the back surface DPb. In short, the function of the functional film 150 is similar to that of a moth-eye film. Different from general moth-eye films, the functional film 150 specifically suppresses obliquely incident light. Therefore, the functional film 150 may also be called a bevel moth-eye film. The mechanism by which the functional film 150 suppresses light reflection will be described in detail below with reference to FIG. 1, FIG. 3, FIG. 4A, FIG. 4B, FIG. 4C and FIG. 4D.

Please refer to FIG. 1, FIG. 3, FIG. 4A, FIG. 4B, FIG. 4C and FIG. 4D. Cross-sections a, b, c and d have the same unit area. On each cross-section a/b/c/d, the ratio of the area occupied by the external environment medium A (for example: air) to the area of the entire cross-section a/b/c/d is X. The ratio of the cross-sectional area of each raised microstructure 152 to the area of the entire cross-section a/b/c/d is Y. The equivalent refractive index on each cross section a/b/c/d is n_{eff}, n_{eff}=N_{A}·X+n₁₅₂·Y, wherein n_{A} is the refractive index of the external environment medium A, and n₁₅₂ is the refractive index of the material of the raised microstructure 152 itself. As the cross-sections d, c, b, and a move away from the pixel 122 along the first oblique direction d1, the proportion of the cross-sectional area of the raised microstructure 152 on the cross-sections d, c, b, and a will be gradually decreased, and the equivalent refractive index n_{eff} also gradually changes from the larger n₁₅₂ to the smaller n_{A}. Through the equivalent refractive index n_{eff} that is continuously and gradually decreased along the first oblique direction d1, the functional film 150 is able to suppress the reflection of light.

Please refer to FIG. 1. In this embodiment, a plurality of raised microstructures 152 may be selectively spaced apart. However, the present disclosure is not limited thereto. In another embodiment that is not shown, the roots of the plurality of raised microstructures 152 may also be directly connected.

Referring to FIG. 1, a portion of the transparent display panel DP is in contact with the functional film 150. In an embodiment, the functional film 150 may be directly disposed on the transparent packaging component 140, and a portion of the transparent display panel DP in contact with the functional film 150 may be a portion of the transparent packaging component 140 (for example, the transparent protective cover 144). However, the present disclosure is not limited thereto.

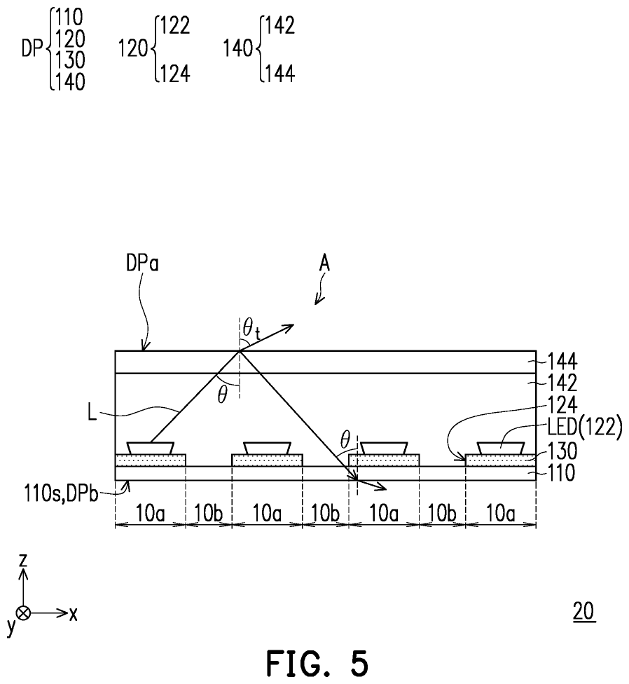

FIG. 5 is a schematic side view of a transparent display device according to a comparative example of the present disclosure. The transparent display device 20 in the comparative example in FIG. 5 is similar to the transparent display device 10 of the embodiment of FIG. 1. The difference between the two is that the transparent display device 20 in the comparative example of FIG. 5 does not include the functional film 150 in FIG. 1.

Referring to FIG. 5, the light beam L emitted by the pixel 122 has a Brewster's angle on the light exit surface DPa of the transparent display panel DP. The Brewster's angle θₘᵢₙ satisfies:

$$tan {θ}_{min} = \frac{{n}_{2}}{{n}_{1}} , \qquad Formula ( 1 )$$

wherein a portion of the transparent display panel DP (for example: the transparent protective cover 144) is in contact with the external environmental medium A, and n₁ is the refractive index of the portion (for example, the transparent protective cover 144) of the transparent display panel DP. The transparent display device 20 is in the external environmental medium A, and n₂ is the refractive index of the external environmental medium A. When the incident angle θ of the light beam L entering the light exit surface DPa from the interior of the transparent display panel DP begins to exceed the Brewster's angle, the amount of the light beam L reflected on the light exit surface DPa toward the back surface DPb will begin to increase dramatically, causing the amount of light leakage from the back surface DPb also began to increase sharply.

Please refer to FIG. 5. The intensity of the light beam L leaking from the back surface DPb of the transparent display panel DP is I(θ), I(θ)=I₀·R(θ)·T(θ), wherein I₀ is the luminous intensity of the light-emitting element LED, R(θ) is the reflectivity of the light beam L on the light exit surface DPa of the display panel DP, T(θ) is the transmittance of the light beam L on the back surface DPb of the display panel DP, and θ is the incident angle of the light beam L incident from the interior of the transparent display panel DP to the light exit surface DPa. The incident angle θ at which the light beam L enters the light exit surface DPa from the interior of the transparent display panel DP is substantially equal to the incident angle at which the light beam L enters the back surface DPb from the interior of the transparent display panel DP. When the refractive index of the portion of the transparent packaging component 140 that is in contact with the external environment medium A is the same as that of the transparent substrate 110 (in other words, the part of the transparent packaging component 140 that is in contact with the external environment medium A has the same material as the transparent substrate 110, for example, both are made of glass), then R(θ)+T(θ)≈1. Since it may be derived from

$$\sqrt{R ( θ ) + T ( θ )} ≦ \frac{[ R ( θ ) + T ( θ ) ]}{2}$$

that R(θ)·T(θ)≤0.25, when R(θ)=50%, I(θ)=I(θ)=I₀·R(θ)·T(θ) has a maximum value, so that the incident angle of R(0)=50% is θₘₐₓ. θₘₐₓ may be calculated based on the following equation (2) and the following equation (3).

$${( \frac{{n}_{1} cos {θ}_{max} - {n}_{2} cos {θ}_{t}}{{n}_{1} cos {θ}_{max} + {n}_{2} cos {θ}_{t}} )}^{2} = 50 \% ; \qquad Formula ( 2 )$$

$${n}_{1} \cdot sin {θ}_{max} = {n}_{2} \cdot sin {θ}_{t} ; \qquad Formula ( 3 )$$

wherein, a portion of the transparent display panel DP is in contact with the external environment medium A, n₁ is a refractive index of the portion of the transparent display panel DP (for example, the transparent protective cover 144), and the transparent display device 20 is in the external environment medium A, n₂ is a refractive index of the external environment medium A (for example: air), the pixel 122 emits the light beam L, and θₜ is an exit angle at which the light beam L exits the portion of the transparent display panel DP (for example, the transparent protective cover 144) and is transmitted toward the external environment medium A. When the incident angle of the light beam L entering the light exit surface DPa from the interior of the transparent display panel DP is θ=θₘₐₓ, the amount of light leaked from the back surface DPb of the transparent display panel DP reaches a maximum value. The portion of the transparent display panel DP in FIG. 5 that is in contact with the external environment medium A is a part of the transparent display panel DP in FIG. 1 that is in contact with the functional film 150.

It can be seen from the description in the above two paragraphs that the amount of light leaking from the back surface DPb of the transparent display panel DP mainly comes from the light beam that enters the light exit surface DPa from the interior of the transparent display panel DP at an incident angle of θₘᵢₙ˜θₘₐₓ and is reflected to the back surface DPb.

Please refer to FIG. 1 and FIG. 5. In an embodiment, if the functional film 150 is able to suppress the reflection of the light beam incident on the light exit surface DPa from the interior of the transparent display panel DP at an incident angle of θₘᵢₙ˜θₘₐₓ, it is possible to suppress the main source of light leakage. In order to suppress the main source of light leakage, the oblique angle (i.e., acute angle α) of the raised microstructure 152 of the functional film 150 is preferably within the range of θₘᵢₙ˜θₘₐₓ. That is, in an embodiment, θₘᵢₙ≤α≤θₘₐₓ.

For example, in an embodiment, the external environment medium A is air, and the refractive index of air is 1, that is, n₂=1 in the aforementioned formulas (1) to (3); a portion of the transparent display panel DP that is in contact with the external environment medium A is the transparent protective cover 144, the material of the transparent protective cover 144 is glass, the refractive index of the glass is 1.5, that is, n₁=1.5 in the aforementioned formulas (1) to (3); substituting n₁=1.5 and n₂=1 into formulas (1)˜(3), it is possible to obtain θₘᵢₙ˜33.7°, θₘₐₓ˜41.4°, please refer to FIG. 1. That is to say, in the condition that the external environment medium A is air and the material of a portion of the transparent display panel DP closest to the functional film 150 is glass, the oblique angle (i.e., acute angle α) of the raised microstructure 152 of the functional film 150 is preferably greater than or equal to 33.7° and less than or equal to 41.4°, but the present disclosure is not limited thereto.

In an embodiment, a GLAD (glancing angle deposition) machine may be adopted to manufacture the functional film 150 (also called a bevel moth-eye film) using physical vapor deposition (PVD) technology. For example, a method of manufacturing the functional film 150 includes the following steps; Step 1: preparing a flat substrate (such as glass, silicon wafer, etc.); Step 2: placing the material (such as silver, aluminum, etc.) into the target; Step 3: inclining the substrate at a certain angle, and the target is physically vapor deposited on the substrate through high-temperature or high-energy sputtering to form a thin film structure with an oblique angle; Step 4: By controlling the oblique angle of the substrate and regulating the rotation direction, the three-dimensional geometry and size of nanoscale thin film structures may be controlled; Step 5: repeating the above steps 1 to 4 until the thin film structure has the required three-dimensional geometry and size; Step 6: performing post-thin film processing according to requirement (for example: covering with a protective layer, unifying surface, etc.), at this stage, the functional film 150 may be manufactured.

It must be noted here that the following embodiments adopt the component numbers and part of the content of the previous embodiments, where the same numbers are used to represent the same or similar components, and the description of the same technical content is omitted. For descriptions of omitted parts, reference may be made to the foregoing embodiments and will not be repeated in the following embodiments.

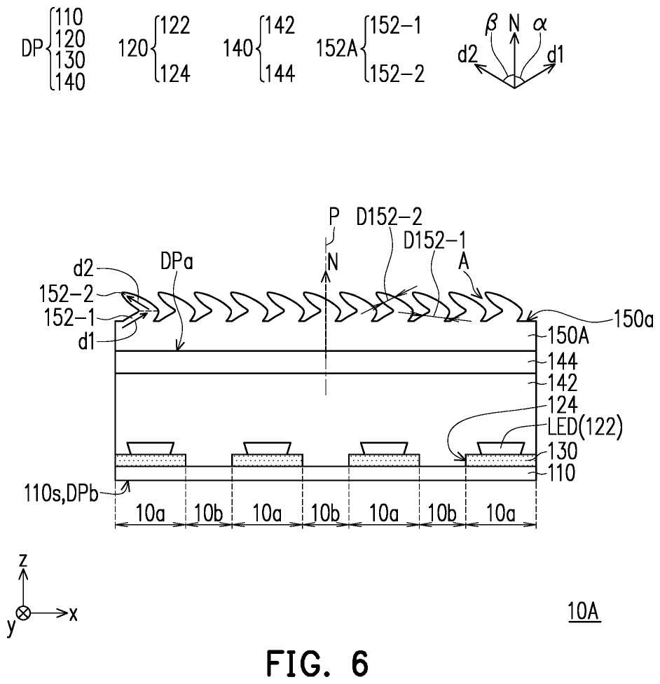

FIG. 6 is a schematic cross-sectional view of a transparent display device according to another embodiment of the present disclosure. The transparent display device 10A of the embodiment of FIG. 6 is similar to the transparent display device 10 of the embodiment of FIG. 1. The difference between the two is that the raised microstructure 152A of the functional film 150A of FIG. 6 is different from the raised microstructure 152A of the functional film 150 of FIG. 1.

In detail, in the embodiment of FIG. 6, each raised microstructure 152A of the functional film 150A includes a first portion 152-1 and a second portion 152-2 connected to the first portion 152-1. The first portion 152-1 extends in the first oblique direction d1, wherein the size D152-1 of the first portion 152-1 of the raised microstructure 152A is gradually decreased along the first oblique direction d1. The second portion 152-2 extends in the second oblique direction d2. The normal direction N of the transparent substrate 110 is located on a normal plane P of the transparent substrate 110. The first oblique direction d1 and the second oblique direction d2 respectively point at opposite sides of the normal plane P. The size D152-2 of the second portion 152-2 of the raised microstructure 152A is gradually decreased along the second oblique direction d2, and the second oblique direction d2 and the normal direction N of the transparent substrate 110 form an acute angle β. In an embodiment, α=β, but the present disclosure is not limited thereto.

In the embodiment of FIG. 6, the first portion 152-1 and the second portion 152-2 of each raised microstructure 152A have different azimuth angles, wherein the azimuth angle of the first portion 152-1 refers to an angle between a reference line (not shown) located on the light exit surface DPa and a vertical projection of the first oblique direction d1 on the light exit surface DPa, and the azimuth angle of the second portion 152-2 refers to the angle between the reference line on the light exit surface DPa and a vertical projection of the second oblique direction d2 on the light exit surface DPa. For example, in an embodiment, the azimuth angles of the first portion 152-1 and the second portion 152-2 of each raised microstructure 152A may be any two of 0°, 90°, 180°, and 270°, but the disclosure is not limited thereto.

In the embodiment of FIG. 6, the raised microstructure 152A of the functional film 150A adopts a multi-bevel tapered structure design, so it is possible to suppress the backside light leakage extremes in multiple specific directions to achieve a backside light leakage suppression effect at a large viewing angle.

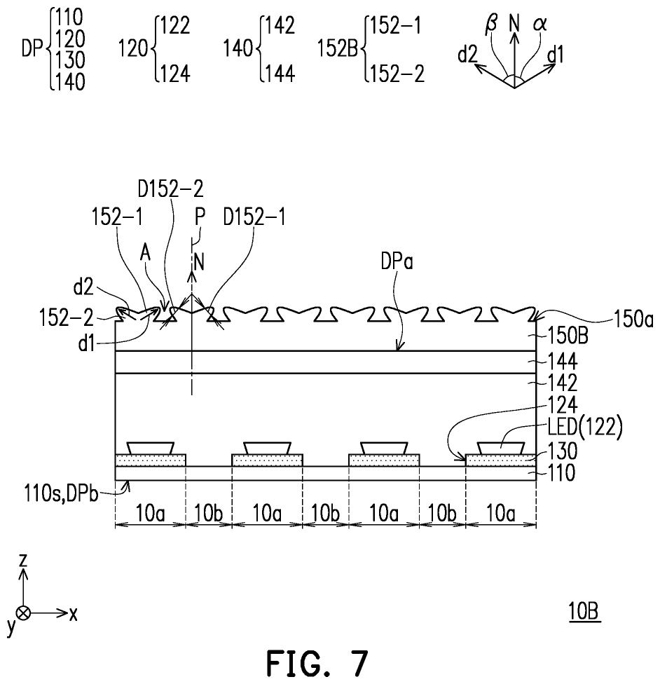

FIG. 7 is a schematic cross-sectional view of a transparent display device according to yet another embodiment of the present disclosure. The transparent display device 10B of the embodiment of FIG. 7 is similar to the transparent display device 10A of the embodiment of FIG. 6, and the difference between the two is that: the raised microstructure 152B of the functional film 150B in FIG. 7 is different from the raised microstructure 152A of the functional film 150A in FIG. 6.

In detail, in the embodiment of FIG. 6, the first portion 152-1 and the second portion 152-2 of the raised microstructure 152A are substantially stacked in the vertical direction (i.e., the third direction z). However, in the embodiment of FIG. 7, the first portion 152-1 and the second portion 152-2 of the raised microstructure 152B are disposed in the horizontal direction (i.e., the second direction x).

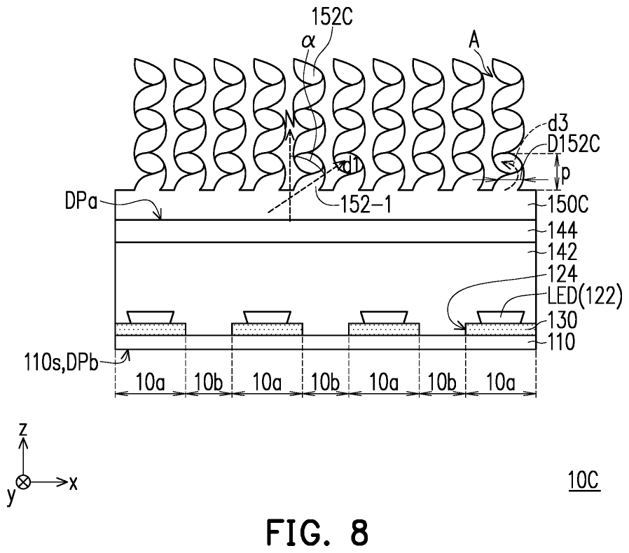

FIG. 8 is a schematic cross-sectional view of a transparent display device according to still another embodiment of the present disclosure. The transparent display device 10C of the embodiment of FIG. 8 is similar to the transparent display device 10 of the embodiment of FIG. 1, and the difference between the two is that: the raised microstructure 152C of the functional film 150C in FIG. 8 is different from the raised microstructure 152 of the functional film 150 in FIG. 1.

Specifically, in the embodiment of FIG. 8, each raised microstructure 152C includes a spiral structure; within a pitch p of the spiral structure, the size D152C of the spiral structure is gradually decreased along the spiral direction d3, and a portion of the spiral direction d3 overlaps with the first oblique direction d1.

In the embodiment of FIG. 8, each raised microstructure 152C is distributed at an azimuth angle of 0°˜360°. The raised microstructure 152C of the functional film 150C adopts a spiral tapered structure design, so it is possible to suppress the backside light leakage extremes in full viewing direction to achieve a backside light leakage suppression effect at a large viewing angle. In an embodiment, 3D printing technology may be used to manufacture the functional film 150C, but the disclosure is not limited thereto.

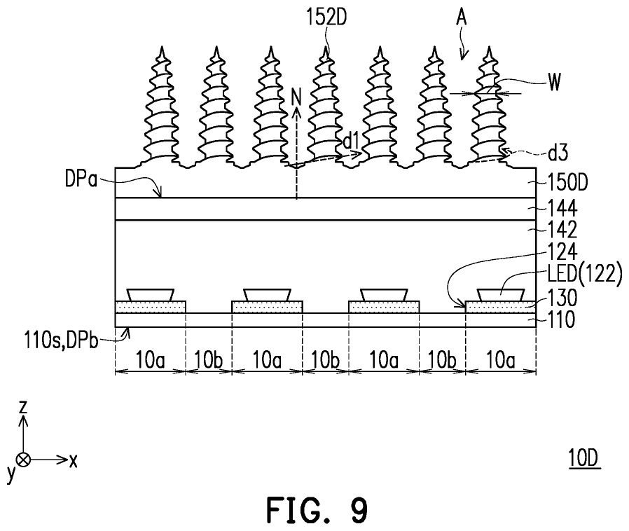

FIG. 9 is a schematic cross-sectional view of a transparent display device according to an embodiment of the present disclosure. The transparent display device 10D of the embodiment of FIG. 9 is similar to the transparent display device 10C of the embodiment of FIG. 8, and the difference between the two is that: the raised microstructure 152D of the functional film 150D in FIG. 9 is different from the raised microstructure 152C of the functional film 150C in FIG. 8.

Specifically, in the embodiment of FIG. 9, the raised microstructure 152D is also a spiral structure. Different from the embodiment of FIG. 8, the width W of the raised microstructure 152D in the second direction x gradually decreases as the raised microstructure 152D moves away from the pixel 122. In other words, the raised microstructure 152D may be a structure that is wider at the bottom and narrower at the top. In an embodiment, 3D printing technology may be used to produce the raised microstructure 152D, but the disclosure is not limited thereto.

What is claimed is:

1. A transparent display device comprising:
a transparent display panel comprising:
a transparent substrate having a plurality of display regions and a plurality of transparent regions; and
a pixel array disposed on the transparent substrate, wherein the pixel array comprises:
a plurality of pixels disposed in an array along a first direction and a second direction, wherein the first direction and the second direction are interleaved, and each of the plurality of pixels overlaps with the corresponding display region; and
a plurality of openings, wherein each of the plurality of openings is surrounded by a portion of the plurality of pixels, and each of the plurality of openings overlaps with the corresponding transparent region; and
a functional film disposed on the transparent display panel, wherein the pixel array is located between the functional film and the transparent substrate, there are a plurality of raised microstructures on a surface of the functional film facing away from the transparent substrate, at least a portion of each of the plurality of raised microstructures extends in a first oblique direction, a size of the at least one portion of each of the plurality of raised microstructures is gradually decreased along the first oblique direction, and the first oblique direction forms an acute angle α with a normal direction of the transparent substrate.

2. The transparent display device according to claim 1, wherein θₘᵢₙ≤α≤θₘₐₓ; θₘᵢₙ satisfies:
$$tan {θ}_{min} = \frac{{n}_{2}}{{n}_{1}} ,$$
a portion of the transparent display panel is in contact with the functional film, n₁ is a refractive index of the portion of the transparent display panel, and the transparent display device is in an external environment medium, n₂ is a refractive index of the external environment medium, θₘₐₓ satisfies: n₁·sin θₘₐₓ=n₂·sin θₜ and
$${( \frac{{n}_{1} cos {θ}_{max} - {n}_{2} cos {θ}_{t}}{{n}_{1} cos {θ}_{max} + {n}_{2} cos {θ}_{t}} )}^{2} = 50 \% ,$$
n₁ is the refractive index of the portion of the transparent display panel, n₂ is the refractive index of the external environmental medium, the one pixel emits a light beam, and θₜ is an exit angle at which the light beam exits the portion of the transparent display panel and is transmitted toward the external environment medium.

3. The transparent display device according to claim 1, wherein 33.7°≤α≤41.4°.

4. The transparent display device according to claim 1, wherein each of the plurality of raised microstructures comprises:
a first portion extending in the first oblique direction, wherein a size of the first portion of the raised microstructure is gradually decreased along the first oblique direction; and
a second portion extending in a second oblique direction, wherein the normal direction of the transparent substrate is located on a normal plane of the transparent substrate, the first oblique direction and the second oblique direction respectively point at opposite sides of the normal plane, a size of the second portion of the raised microstructure is gradually decreased along the second oblique direction, and the second oblique direction and the normal direction of the transparent substrate form an acute angle β.

5. The transparent display device according to claim 1, wherein each of the plurality of raised microstructures comprises a spiral structure; within a pitch of the spiral structure, a size of the spiral structure is gradually decreased along a spiral direction, and a portion of the spiral direction overlaps with the first oblique direction.
